(19) United States
(12) Patent Application Publication
(10) Pub. No.: US 2008/0102206 A1
(43) Pub. Date: May 1, 2008

(54) Multilayered coatings for use on electronic devices or other articles

(76) Inventor: Sigurd Wagner, Princeton, NJ (US)

Correspondence Address: KENYON & KENYON LLP, 1500 K STREET N.W., SUITE 700, WASHINGTON, DC, 20005, US

(21) Appl. No.: 11/783,362

(22) Filed: Apr. 9, 2007

Related U.S. Application Data
(60) Provisional application No. 60/856,047, filed on Nov. 1, 2006.

(51) Int. Cl. C23C 16/00

(52) U.S. Cl. 427/255.7

(57) ABSTRACT

A method for forming a multilayered coating over a surface is disclosed. The method comprises providing a single source of precursor material and transporting the precursor material to a reaction location adjacent a surface to be coated. A first layer is deposited over the surface by chemical vapor deposition using the single source of precursor material, under a first set of reaction conditions. A second layer is deposited over the surface by chemical vapor deposition using the single source of precursor material, under a second set of reaction conditions. The first layer may have a predominantly polymeric component and the second layer may have a predominantly non-polymeric component. The chemical vapor deposition process may be plasma-enhanced and may be performed using a reactant gas. The precursor material may be an organo-silicon compound, such as a siloxane. The first and second layers may comprise various types of polymeric materials, such as silicone polymers, and various types of non-polymeric materials, such as silicon oxides. The multilayered coating may have various characteristics suitable for use with organic light-emitting devices, such as optical transparency, impermeability, and/or flexibility.

This application incorporates by reference in its entirety, U.S. patent application Ser. No. ______ , entitled “Mixed Composition Layers for Use as Coatings on Electronic Devices or Other Articles,” by Sigurd Wagner and Prashant Mandlik, identified with Attorney Docket No. 10020/35301, and filed on the same date as this application.

The claimed invention was made with support from the United States Government, under Contract No. W911QX-06-C-0017, awarded by the Army Research Office. The U.S. Government may have certain rights in this invention.

### TECHNICAL FIELD

The present invention relates to barrier coatings for electronic devices.

### BACKGROUND

Organic electronic devices, such as organic light-emitting devices (OLEDs), are vulnerable to degradation when exposed to water vapor or oxygen. A protective barrier coating over the OLED to reduce its exposure to water vapor or oxygen could help to improve the lifetime and performance of the device. Films of silicon oxide, silicon nitride, or aluminum oxide, which have been successfully used in food packaging, have been considered for use as barrier coatings for OLEDs. However, these inorganic films tend to contain microscopic defects which allow the diffusion of water vapor and oxygen through the film. In some cases, the defects open as cracks in the brittle film. While the amount of diffusion may be acceptable for food products, it is not acceptable for OLEDs. To address this problem, multilayered barrier coatings that use alternating inorganic and polymer layers have been tested on OLEDs and found to have improved resistance to water vapor and oxygen penetration. But the process for fabricating these multilayered coatings can be cumbersome and costly. Thus, there is a need for other methods of fabricating multilayered coatings suitable for use in protecting OLEDs.

### SUMMARY

In one aspect, the present invention provides a method for forming a coating over a surface, comprising: (a) providing a single source of precursor material; (b) transporting the precursor material to a reaction location adjacent a surface to be coated; (c) depositing a first layer over the surface by chemical vapor deposition using the single source of precursor material, under a first set of reaction conditions, the first layer having a weight ratio of polymeric to non-polymeric material of 100:0 to 75:25; and (d) depositing a second layer over the surface by chemical vapor deposition using the single source of precursor material, under a second set of reaction conditions, the second layer having a weight ratio of polymeric to non-polymeric material of 0:100 to 25:75.

The chemical vapor deposition process may be plasma-enhanced and may be performed using a reactant gas. The precursor material may be an organo-silicon compound, such as a siloxane. The polymeric layer may comprise various types of polymeric materials, such as silicone polymers, and the non-polymeric layer may comprise various types of non-polymeric materials, such as silicon oxides. The multilayered coating may have various characteristics suitable for use with organic light-emitting devices, such as optical transparency, impermeability, and/or flexibility.

### BRIEF DESCRIPTION OF THE DRAWINGS

FIG. 1 shows a schematic diagram of a PE-CVD apparatus that can be used for implementing certain embodiments of the present invention.

FIG. 2 shows a cross-sectional view of a portion of an OLED having a multilayered barrier coating.

FIG. 3 shows the results of an experiment comparing the degradation of a coated OLED versus a bare OLED.

### DETAILED DESCRIPTION

In one aspect, the present invention provides a method for forming a multilayered coating over a surface. The method comprises depositing a polymeric layer and a non-polymeric layer over a surface by chemical vapor deposition. The non-polymeric layer is deposited using a single source of precursor material, alone or with the addition of a reactant gas, under a first set of reaction conditions. The polymeric layer is deposited using the same single source of precursor material, alone or with the addition of a reactant gas, under a second set of reaction conditions.

As used herein, the term “non-polymeric” refers to a material made of molecules having a well-defined chemical formula with a single, well-defined molecular weight. A “non-polymeric” molecule can have a significantly large molecular weight. In some circumstances, a non-polymeric molecule may include repeat units. As used herein, the term “polymeric” refers to a material made of molecules that have repeating subunits that are covalently linked, and that has a molecular weight that may vary from molecule to molecule because the polymerizing reaction may result in different numbers of repeat units for each molecule. Polymers include, but are not limited to homopolymers and copolymers such as block, graft, random, or alternating copolymers, as well as blends and modifications thereof. Polymers include, but are not limited to, polymers of carbon or silicon.

A “polymeric layer” consists essentially of polymeric material, but may contain an incidental amount (up to 5%) of non-polymeric material. This incidental amount is sufficiently small that a person of ordinary skill in the art would nevertheless consider the layer to be polymeric. Likewise, a “non-polymeric layer” consists essentially of non-polymeric material, but may contain an incidental amount (up to 5%) of polymeric material. This incidental amount is sufficiently small that a person of ordinary skill in the art would nevertheless consider the layer to be non-polymeric.

The polymeric/non-polymeric composition of a layer may be determined using various techniques, including wetting contact angles of water droplets, IR absorption, hardness, and flexibility. For example, the wetting contact angle of a purely polymeric layer formed by HMDSO is about 103°. As such, in some instances, the first layer has a wetting contact angle in the range of 60° to 115°, and preferably in the range of 75° to 115°. The wetting angle of a pure silicon oxide layer is about 32°. As such, in some instances, the second layer has a wetting contact angle in the range of 0° to 60°. Note that the wetting contact angle is a measure of composition if determined on the surface of an as-deposited film. Because the wetting contact angle can vary greatly by post-deposition treatments, measurements taken after such treatments may not accurately reflect the layer's composition. It is believed that these wetting contact angles are applicable to a wide range of layers formed from organo-silicon precursors. Preferably, the first layer has a nano-indentation hardness in the range of 1 MPa to 3 Gpa, and more preferably, in the range of 0.2 to 2 GPa. Preferably, the second layer has a nano-indentation hardness in the range of 10 GPa to 200 GPa, and more preferably, in the range of 10 to 20 GPa. In certain instances, at least one of the layers has a surface roughness (root-mean-square) in the range of 0.1 nm to 10 nm, and more preferably, in the range of 0.2 nm to 0.35 nm. In certain instances, at least one of the layers, when deposited as a 4 μm thick layer on a 50 μm thick polyimide foil substrate, is sufficiently flexible that no microstructural changes are observed after at least 55,000 rolling cycles on a 1 inch diameter roll at a tensile strain (ε) of 0.2%. In certain instances, at least one of the layers is sufficiently flexible that no cracks appear under a tensile strain (ε) of at least 0.35% (a tensile strain level which would normally crack a 4 μm pure silicon oxide layer, as considered by a person of ordinary skill in the art).

Single layer barrier coatings made of purely non-polymeric materials, such as silicon oxide, can have various advantages relating to optical transparency, good adhesion, and good film stress. However, these non-polymeric layers tend to contain microscopic defects which allow the diffusion of water vapor and oxygen through the coating. Alternating polymeric layers and non-polymeric layers can reduce the permeability of the coating. Without intending to be bound by theory, the inventors believe that the polymeric layers mask and/or planarize the defects in the adjacent non-polymeric layers, thereby reducing diffusion through the defects.

As used herein, “single source of precursor material” refers to a source that provides all the precursor materials that are necessary to form both the polymeric layer and the non-polymeric layer when the precursor material is deposited by CVD, with or without a reactant gas added. This is intended to exclude methods where the polymeric layer is formed using one precursor material, and the non-polymeric layer is formed using a different precursor material. By using a single source of precursor material, the deposition process is simplified. For example, a single source of precursor material will obviate the need for separate streams of precursor materials and the attendant need to monitor the separate streams.

The precursor material may be a single compound or a mixture of compounds. Where the precursor material is a mixture of compounds, in some cases, each of the different compounds in the mixture is, by itself, able to independently serve as a precursor material. For example, the precursor material may be a mixture of hexamethyl disiloxane (HMDSO) and dimethyl siloxane (DMSO).

In some cases, plasma-enhanced CVD (PE-CVD) may be used for deposition of each layer. PE-CVD may be desirable for various reasons, including low temperature deposition, uniform coating formation, and controllable process parameters. Various PE-CVD processes which are suitable for use in the present invention are known in the art, including those that use RF energy to generate the plasma.

The precursor material is a material that is capable of forming both a polymeric material and a non-polymeric material when deposited by chemical vapor deposition. Various such precursor materials are suitable for use in the present invention and are chosen for their various characteristics. For example, a precursor material may be chosen for its content of chemical elements, its stoichiometric ratios of the chemical elements, and/or the polymeric and non-polymeric materials that are formed under CVD. For instance, organo-silicon compounds, such as siloxanes, are a class of compounds suitable for use as the precursor material. Representative examples of siloxane compounds include hexamethyl disiloxane (HMDSO) and dimethyl siloxane (DMSO). When deposited by CVD, these siloxane compounds are able to form polymeric materials, such as silicone polymers, and non-polymeric materials, such as silicon oxide. The precursor material may also be chosen for various other characteristics such as cost, non-toxicity, handling characteristics, ability to maintain liquid phase at room temperature, volatility, molecular weight, etc.

Other organo-silicon compounds suitable for use as a precursor material include methylsilane; dimethylsilane; vinyl trimethylsilane; trimethylsilane; tetramethylsilane; ethylsilane; disilanomethane; bis(methylsilano)methane; 1,2-disilanoethane; 1,2-bis(methylsilano)ethane; 2,2-disilanopropane; 1,3,5-trisilano-2,4,6-trimethylene, and fluorinated derivatives of these compounds. Phenyl-containing organo-silicon compounds suitable for use as a precursor material include: dimethylphenylsilane and diphenylmethylsilane. Oxygen-containing organo-silicon compounds suitable for use as a precursor material include: dimethyldimethoxysilane; 1,3,5,7-tetramethylcyclotetrasiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3-dimethyldisiloxane; 1,3,5,7,9-pentamethylcyclopentasiloxane; hexamethoxydisiloxane, and fluorinated derivatives of these compounds. Nitrogen-containing organo-silicon compounds suitable for use as a precursor material include: hexamethyldisilazane; divinyltetramethyldisilizane; hexamethylcyclotrisilazane; dimethylbis(N-methylacetamido)silane; dimethylbis-(N-ethylacetamido)silane; methylvinylbis(N-methylacetamido)silane; methylvinylbis(N-butylacetamido)silane; methyltris(N-phenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide.

When using PE-CVD, the precursor material may be used in conjunction with a reactant gas that reacts with the precursor material in the PE-CVD process. The use of reactant gases in PE-CVD is known in the art and various reactant gases are suitable for use in the present invention, including oxygen-containing gases (e.g., O₂, ozone, water) and nitrogen-containing gases (e.g., ammonia). The reactant gas may be used to vary the stoichiometric ratios of the chemical elements present in the reaction mixture. For example, when a siloxane precursor material is used with an oxygen or nitrogen-containing reactant gas, the reactant gas will change the stoichiometric ratios of oxygen or nitrogen in relation to silicon and carbon in the reaction mixture. This stoichiometric relation between the various chemical elements (e.g., silicon, carbon, oxygen, nitrogen) in the reaction mixture may be varied in several ways. One way is to vary the concentration of the precursor material or the reactant gas in the reaction. Another way is to vary the flow rates of the precursor material or the reactant gas into the reaction. Another way is to vary the type of precursor material or reactant gas used in the reaction.

The type of material formed by chemical vapor deposition of the precursor materials will depend upon the reactions conditions under which the CVD process takes place. The reaction conditions may be defined by the composition of the reaction mixture, including the type of precursor material and reactant gas used, and the quantities of those materials. For example, the reaction mixture may contain a siloxane gas (e.g., HMDSO or DMSO) as the precursor material and oxygen as a reactant gas. The quantities of the reaction mixture materials may be adjusted by varying the flow rates of the materials. For example, by varying the flow rates of the precursor material and the reactant gas, different types of materials may be deposited. In some cases, the reactant gas is absent from the reaction mixture (e.g., the flow rate of the reactant gas is set at zero). Other parameters which define the reaction conditions include various process parameters, such as RF power and frequency, deposition pressure, temperature, and deposition time.

In the methods of the present invention, a first set of reaction conditions is used to deposit a first layer by CVD having a predominantly polymeric component. The precursor material may form various types of non-polymeric materials, depending upon the reaction conditions that are used. The non-polymeric material may be inorganic or organic. For example, where organo-silicon compounds are used as the precursor material in combination with an oxygen-containing reactant gas, the non-polymeric material may include silicon oxides, such as SiO, Sio₂, and mixed-valence oxides SiOₓ. When deposited with a nitrogen-containing reactant gas, the non-polymeric material may include silicon nitrides (SiNe). Other non-polymeric materials that may be formed include silicon carbide, silicon oxycarbide, and silicon oxynitrides. Preferably, the first layer has a weight ratio of polymer to non-polymer of 100:0 to 75:25.

A second set of reactions conditions is used to deposit a second layer by CVD having a predominantly non-polymeric component. The precursor material may form various types of polymeric materials, depending upon the reaction conditions that are used. The polymeric material may be inorganic or organic. For example, where organo-silicon compounds are used as the precursor material, the deposited mixed layer may include polymer chains of Si—O bonds, Si—C bonds, or Si—O—C bonds to form polysiloxanes, polycarbosilanes, and polysilanes, as well as organic polymers. Preferably, the second layer has a weight ratio of polymer to non-polymer of 0:100 to 25:75.

Thus, by using the methods of the present invention, it is possible to form a multilayered coating having alternating predominantly polymeric and predominantly non-polymeric layers. The coating can have characteristics suitable for use in various applications. Such characteristics include optical transparency, impermeability, flexibility, thickness, adhesion, and other mechanical properties. For example, one or more of these characteristics may be adjusted by varying the total thickness of the coating, the thickness of the polymeric layers relative to the thickness of the non-polymeric layers, and the number of alternating layers. For instance, the coating may have 3 to 5 pairs of polymeric/non-polymeric layers to achieve the desired level of impermeability. In some instances, the polymeric layers may have a thickness of 0.1 μm to 10 μm and the non-polymeric layers may have a thickness of 0.05 μm to 10 μm. Other numbers and thicknesses of layers are also possible and the thickness of each layer may be varied independently.

One of the ways in which the layers may be characterized is by the wetting contact angle of a water droplet, which is a technique well known in the art. One way to determine whether a multilayered coating has alternating layers that have predominantly polymeric and predominantly non-polymeric components is to measure the wetting angle. For example, if the first layer has a wetting angle greater than 60° (or between 60° and 115°), and the second layer has a wetting angle less than 60° (or between 60° and 0°), the first layer would be considered to have significantly more polymer than the second layer. By way of example, the contact angle for pp-HMDSO, a polymer, is 103° and the contact angle for SiO2, a non-polymer, is 32°. In some cases, the multilayered coating may be considered to have alternating layers if the wetting contact angles between the first and second layers differ by a certain amount. For example, the multilayered coating may be characterized as having alternating layers, with the first layer being more polymeric, where the first layer has a wetting contact angle that is at least 15° greater than the second layer.

The polymeric and non-polymeric layers may be deposited in any order. In some cases, the non-polymeric layer is deposited before the polymeric layer. In other cases, the polymeric layer is deposited before the non-polymeric layer. For example, a polymeric layer may first be deposited on a surface to serve as a planarization layer.

The multilayered coating may be deposited over various types of articles. In some cases, the article may be an organic electronic device, such as an OLED. For an OLED, the multilayered coating may serve as a barrier coating that resists permeation of water vapor and oxygen. For example, a multilayered coating having a water vapor transmission rate of less than 10⁻⁶ g/m²/day and/or an oxygen transmission rate of less than 10⁻³ g/m²/day may be suitable for protecting OLEDs. In some cases, the thickness of the multilayered coating can range from 0.5 to 10 μm, but other thicknesses are also possible depending upon the application. Also, multilayered coatings having a thickness and material composition that confers optical transparency may be suitable for use with OLEDs. For use with flexible OLEDs, the multilayered coating may be designed to have the desired amount of flexibility. In some cases, the multilayered coating may be used on other articles that are sensitive to degradation upon exposure to the environment, such as pharmaceuticals, medical devices, biologic agents, biological samples, biosensors, or other sensitive measuring equipment.

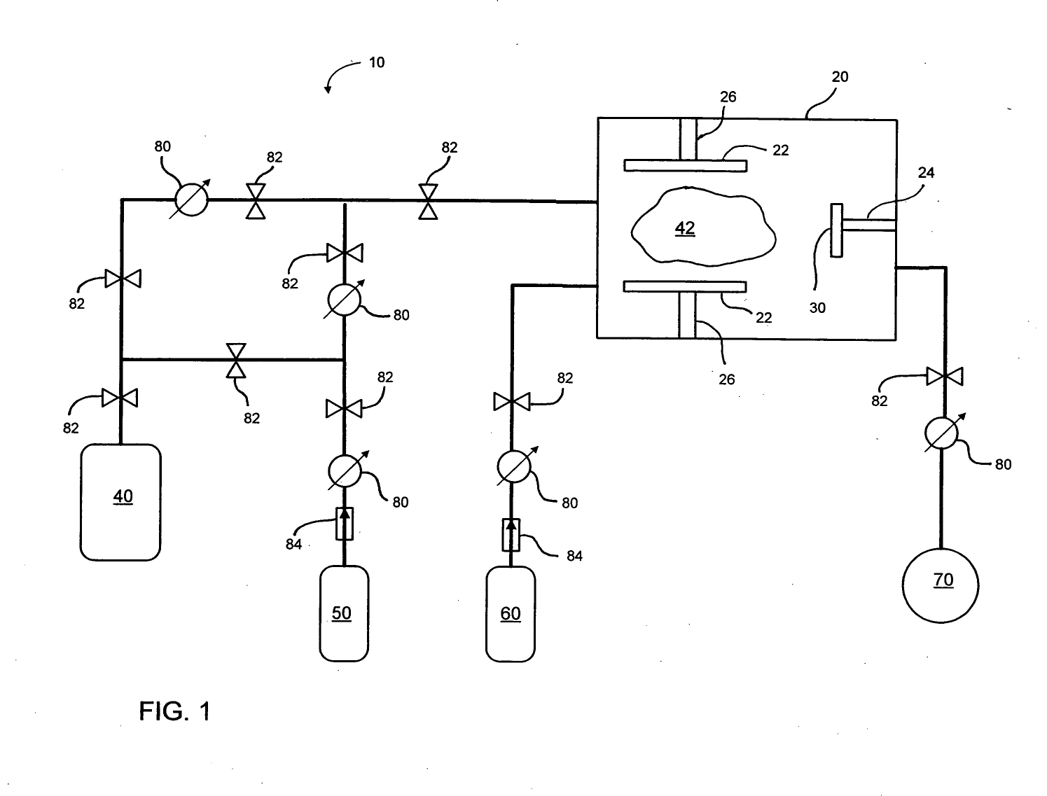

Any of various types of CVD reactors may be used to implement the methods of the present invention. As one example, FIG. 1 shows a PE-CVD apparatus 10 that can be used to implement certain embodiments of the present invention. PE-CVD apparatus 10 comprises a reaction chamber 20 in which an electronic device 30 is loaded onto a holder 24. Reaction chamber 20 is designed to contain a vacuum and a vacuum pump 70 is connected to reaction chamber 20 to create and/or maintain the appropriate pressure. An N₂ gas tank 50 provides N₂ gas for purging apparatus 10. Reaction chamber 20 may further include a cooling system to reduce the heat that is generated by the reaction.

For handling the flow of gases, apparatus 10 also includes various flow control mechanisms (such as mass flow controllers 80, shut-off valves 82, and check valves 84) which may be under manual or automated control. A precursor material source 40 provides a precursor material (e.g., HMDSO in liquid form) which is vaporized and fed into reaction chamber 20. In some cases, the precursor material may be transported to reaction chamber 20 using a carrier gas, such as argon. A reactant gas tank 60 provides the reactant gas (e.g., oxygen), which is also fed into reaction chamber 20. The precursor material and reactant gas flow into reaction chamber 20 to create a reaction mixture 42 adjacent electronic device 30. The pressure inside reaction chamber 20 may be adjusted further to achieve the deposition pressure. Reaction chamber 20 includes a set of electrodes 22 mounted on electrode standoffs 26, which may be conductors or insulators. A variety of arrangements of device 30 and electrodes 22 are possible. Diode or triode electrodes, or remote electrodes may be used. Device 30 may be positioned remotely as shown in FIG. 1, or may be mounted on one or both electrodes of a diode configuration.

Electrodes 22 are supplied with RF power to create plasma conditions in the reaction mixture 42. Reaction products created by the plasma are deposited onto electronic device 30. The reaction is allowed to proceed for a period of time sufficient to deposit a layer on electronic device 30. The reaction time will depend upon various factors, such as the position of device 30 with respect to electrodes 22, the type of layer to be deposited, the reaction conditions, the desired thickness of the layer, the precursor material, and the reactant gas. The reaction time may be a duration between 5 seconds to 5 hours, but longer or shorter times may also be used depending upon the application. The preceding steps may then be repeated under a different set of reaction conditions to deposit a different type of layer. Device 30 may require heating or cooling to bring or hold its temperature at a desired value.

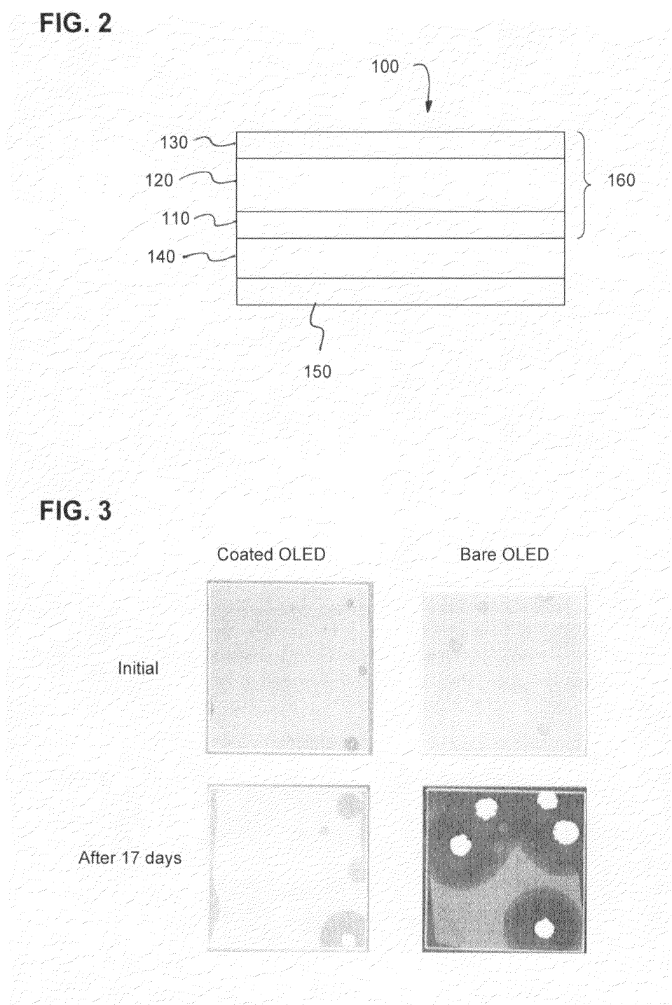

FIG. 2 shows a cross-sectional view of a portion of an OLED 100, which comprises a body of an OLED 140 on a substrate 150 and a multilayered barrier coating 160 deposited by PE-CVD using HMDSO as the precursor material and oxygen as the reactant gas. The characteristics of each layer in the multilayered coating and the reaction conditions under which they were deposited are shown in Table 1 below. Layer 110 of silicon oxide was deposited over the body of OLED 140 using the reaction conditions shown. Layer 120 of silicon polymer was deposited over layer 110 using a different set of reaction conditions, which included a higher flow rate or HMDSO and a reduced flow rate of oxygen. Finally, layer 130 of silicon oxide was deposited over layer 120 using the same reaction conditions as layer 110.

TABLE 1

| | HMDSO | HMDSO | | | | | |
|---|---|---|---|---|---|---|---|
| | source | gas flow | O₂ gas | | | | Film |
| | temp | rate | flow rate | Pressure | RF power | Deposition | thickness |
| Layer | (° C.) | (sccm) | (sccm) | (m torr) | (W) | time (min) | (Å) |
| 110 (oxide) | 33 | 0.4 | 300 | 600 | 5 | 30 | 800 |
| 120 (polymer) | 33 | 10 | 13 | 130 | 18 | 10 | 1600 |
| 130 (oxide) | 33 | 0.4 | 300 | 600 | 5 | 30 | 800 |

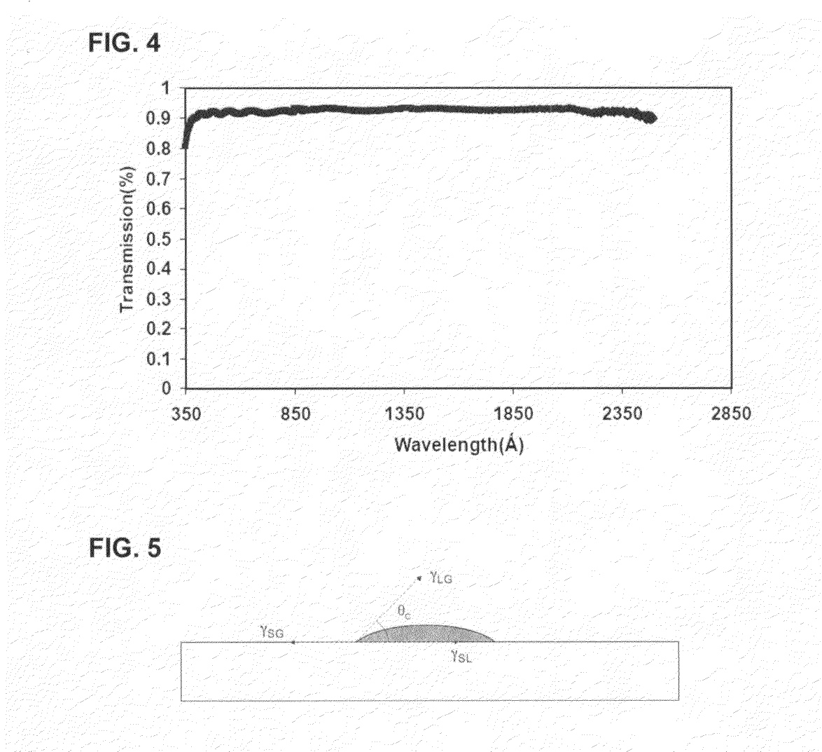

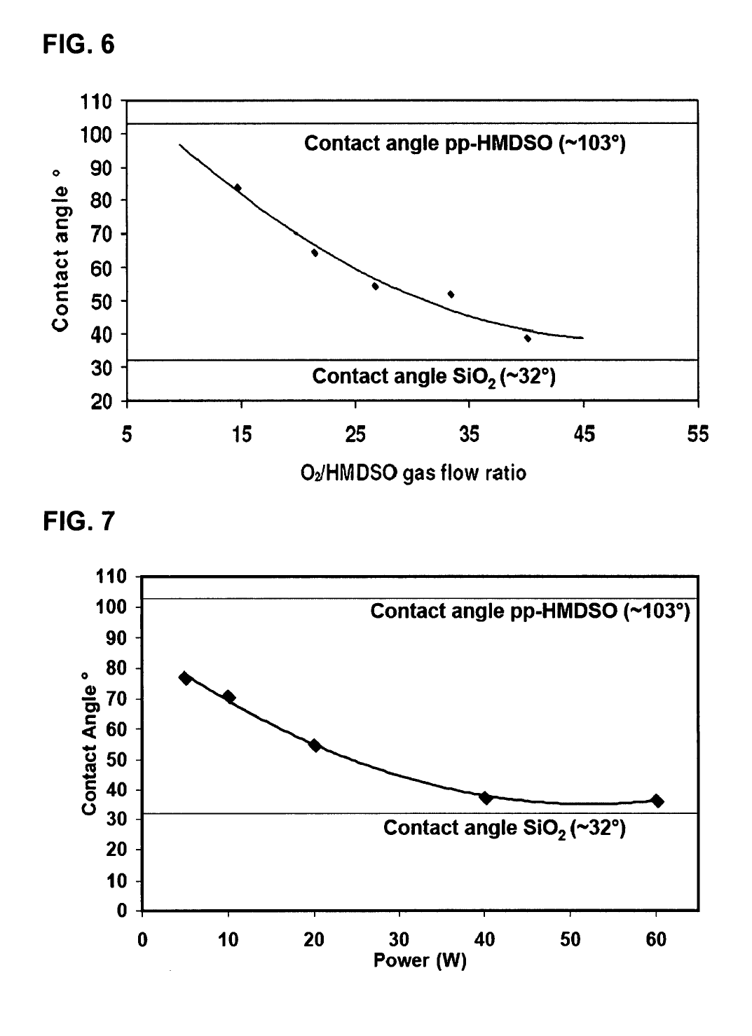

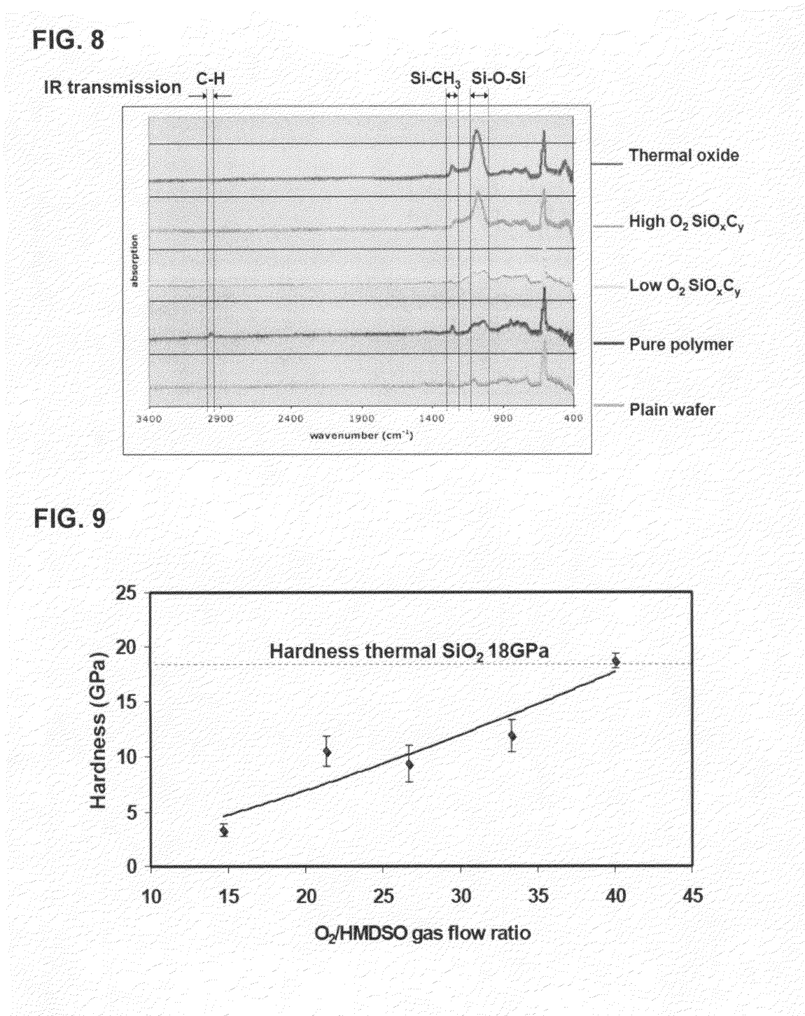

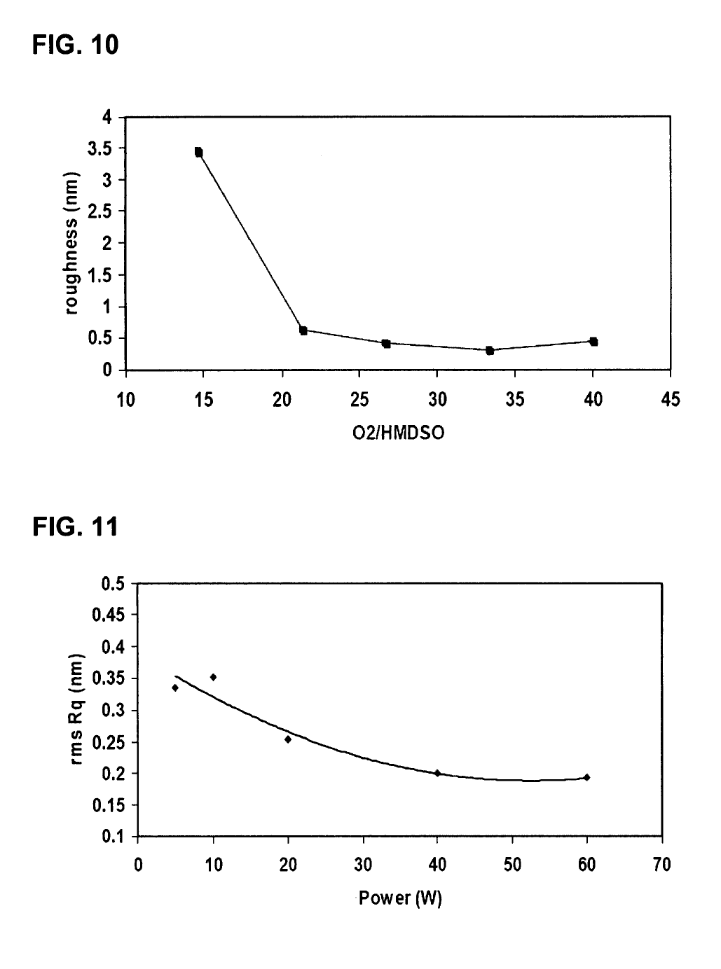

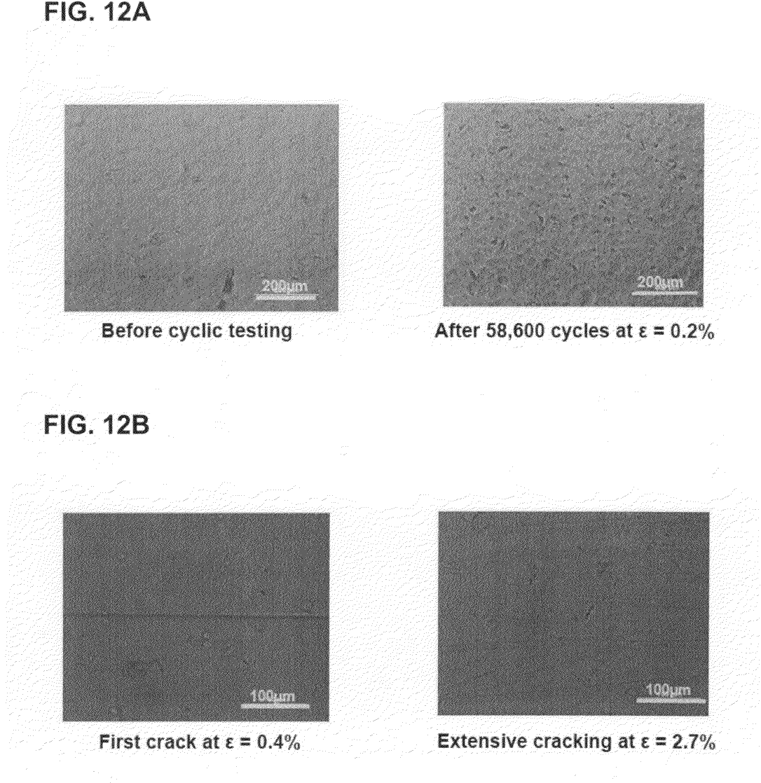

FIG. 3 shows the results of an experiment comparing the degradation of the coated OLED of FIG. 2 to a bare OLED. Both OLEDs were operated under 6.5 V DC current for 17 days at room temperature in ambient air. The images in FIG. 3 show the condition of the OLEDs at the initial time point and after 17 days. In comparison to the bare OLED, the coated OLED sustained significantly less deterioration. These results demonstrate that the methods of the present invention can provide a coating that effectively protects against the degradative effects of environmental exposure.

FIG. 4 shows the optical transmission spectrum of a 6 μm layer deposited using HMDSO at a source temperature of 33° C. and a flow rate of 1.5 sccm, with O₂ at a flow rate of 50 sccm, under a deposition pressure of 150 mtorr, RF power of 60 W, and deposition time of 135 minutes. This layer has greater than 90% transmittance from the near-UV to the near-IR spectrum.

FIG. 5 shows how the contact angle of a water droplet on a film is measured. FIG. 6 is a plot of the contact angles of several layers formed under various O₂/HMDSO gas flow ratios in comparison to the contact angles of a pure SiO₂ film and a pure polymer film. The contact angles of the layers approach that of a pure SiO₂ film as the oxygen flow rate in the deposition process increases.

FIG. 7 is a plot of the contact angles of several layers formed under various power levels applied during the PE-CVD process. The contact angles of the layers approach that of a pure SiO₂ film as the power level increases, which may be due to the fact that higher power levels make O₂ a stronger oxidant. FIG. 8 shows the infrared absorption spectra of layers formed using a relatively high O₂ flow and a relatively low O₂ flow in comparison to films of pure SiO₂ (thermal oxide) or pure polymer. The high O₂ layer shows strong peaks in the Si—O—Si band. The nominal peaks in the Si—CH₃ band for the thermal oxide (pure SiO₂) film are believed to be related to Si—O vibrations. FIG. 9 is a plot of the nano-indentation hardness of various layers formed under various O₂/HMDSO gas flow ratios in comparison to the hardness of a pure SiO₂ film. The hardness of the layers increase as the oxygen flow rate in the deposition process increases, and these layers can be nearly as hard pure SiO₂ films, and yet be tough and highly flexible.

FIG. 10 is a plot of the surface roughness (root-mean-square), measured by atomic force microscopy, of several layers formed under various O₂/HMDSO gas flow ratios, and shows that the surface roughness decreases with increasing O₂ flow rates used in the deposition process. FIG. 11 is a plot of the surface roughness (root-mean-square), measured by atomic force microscopy, of several layers formed under various power levels, and shows that the surface roughness decreases with increasing power levels used in the deposition process.

FIGS. 12A and 12B show optical micrographs of the surface of a 4 μm layer deposited at a source temperature of 33° C., an HMDSO gas flow rate of 1.5 sccm, an O₂ flow rate of 50 sccm, a pressure of 150 mtorr, and an RF power of 60 W, on a 50 μm thick Kapton polyimide foil. In FIG. 12A, the images were obtained before and after the coated foil was subjected to cyclic rolling on a 1 inch diameter roll (tensile strain ε=0.2%). No microstructural changes were observed after 58,600 rolling cycles. In FIG. 12B, the coated foil was subjected to increasing tensile strain, and the images were obtained after the appearance of first cracking (roll diameter of 14 mm) and after extensive cracking (roll diameter of 2 mm). These flexibility results demonstrate that the methods of the present invention can provide a coating that is highly flexible.

What is claimed is:

1. A method for forming a coating over a surface, comprising:
providing a single source of precursor material;
transporting the precursor material to a reaction location adjacent a surface to be coated;
depositing a first layer having a weight ratio of polymeric to non-polymeric material of 100:0 to 75:25 over the surface by chemical vapor deposition using the single source of precursor material, under a first set of reaction conditions; and
depositing a second layer having a weight ratio of polymeric to non-polymeric material of 0:100 to 25:75 over the surface by chemical vapor deposition using the single source of precursor material, under a second set of reaction conditions.

2. The method of claim 1, wherein the chemical vapor deposition in the first and second set of reaction conditions is plasma-enhanced.

3. The method of claim 2, further comprising providing a reactant gas and transporting the reactant gas to the reaction location in the first set of reaction conditions, the second set of reactions conditions, or both.

4. The method of claim 3, wherein the reactant gas is oxygen.

5. The method of claim 3, wherein the reactant gas is present in both sets of reaction conditions, and wherein the flow rate of the reactant gas in the first set of reaction conditions is at least 10% greater than the flow rate of the reactant gas in the second set of reaction conditions.

6. The method of claim 1, wherein the first set of reaction conditions and second set of reaction conditions each independently includes a parameter selected from the group consisting of: gas flow rates, gas pressure, process pressure, DC power, RF power, RF frequency, substrate temperature, and deposition time.

7. The method of claim 1, wherein the precursor material comprises an organo-silicon compound.

8. The method of claim 7, wherein the precursor material comprises a single organo-silicon compound.

9. The method of claim 7, wherein the precursor material comprises a mixture of organo-silicon compounds.

10. The method of claim 7, wherein the organo-silicon compound is hexamethyl disiloxane or dimethyl siloxane.

11. The method of claim 7, wherein the organo-silicon compound is selected from the group consisting of: methylsilane; dimethylsilane; vinyl trimethylsilane; trimethylsilane; tetramethylsilane; ethylsilane; disilanomethane; bis(methylsilano)methane; 1,2-disilanoethane; 1,2-bis(methylsilano)ethane; 2,2-disilanopropane; 1,3,5-trisilano-2,4,6-trimethylene; dimethylphenylsilane; diphenylmethylsilane; dimethyldimethoxysilane; 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane; hexamethyldisilazane; divinyltetramethyldisilizane; hexamethylcyclotrisilazane; dimethylbis(N-methylacetamido)silane; dimethylbis-(N-ethylacetamido)silane; methylvinylbis(N-methylacetamido)silane; methylvinylbis(N-butylacetamido)silane; methyltris(N-phenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide.

12. The method of claim 1, wherein the non-polymeric material consists essentially of an inorganic material.

13. The method of claim 12, wherein the inorganic material is silicon oxide.

14. The method of claim 1, wherein the polymeric material consists essentially of a silicone polymer.

15. The method of claim 1, further comprising depositing a third layer over the first and second layers by chemical vapor deposition using the single source of precursor material, under a third set of reaction conditions.

16. The method of claim 1, wherein depositing the second layer occurs prior to depositing the first layer.

17. The method of claim 1, further comprising repeating at least once, in an alternating manner, the steps of depositing a layer having a weight ratio of polymeric to non-polymeric material of 100:0 to 75:25 and a layer having a weight ratio of polymeric to non-polymeric material of 0:100 to 25:75, wherein the reaction conditions for depositing each layer is independently selected.

18. The method of claim 1, wherein less than 10 nm of material is deposited during the transition between depositing each layer.

19. The method of claim 1, wherein the surface is the surface of a substrate for an electronic device.

20. The method of claim 19, wherein the electronic device is an organic light-emitting device.

21. The method of claim 19, wherein the electronic device is a solar cell.

22. The method of claim 1, wherein the surface is the surface of an electronic device.

23. The method of claim 22, wherein the electronic device is an organic light-emitting device.

24. The method of claim 22, wherein the electronic device is a solar cell.

25. The method of claim 1, wherein the first layer, as deposited, has a wetting contact angle of a water droplet in the range of 60° to 115°.

26. The method of claim 1, wherein the first layer, as deposited, has a wetting contact angle of a water droplet in the range of 75° to 115°.

27. The method of claim 1, wherein the second layer, as deposited, has a wetting contact angle of a water droplet in the range of 0° to 60°.

28. The method of claim 1, wherein the first layer, as deposited, has a wetting contact angle that is at least 150 different from that of the second layer, as deposited.

29. The method of claim 1, wherein the first layer has a nano-indentation hardness in the range of 0.2 to 2 GPa.

30. The method of claim 1, wherein the second layer has a nano-indentation hardness in the range of 10 to 20 GPa.

31. The method of claim 1, wherein at least one of the layers has a surface roughness (root-mean-square) in the range of 0.1 to 10 nm.

32. The method of claim 1, wherein at least one of the layers, when deposited as a 4 μm layer on a 50 μm thick polyimide foil, is sufficiently flexible that no microstructural changes are observed after at least 55,000 rolling cycles on a 1 inch diameter roll at a tensile strain (ε) of 0.2%.

33. The method of claim 1, wherein at least one of the layers, when deposited as a 4 μm layer on a 50 μm thick polyimide foil, is sufficiently flexible that no cracks appear under a tensile strain (ε) of at least 0.35%.
